(19) United States
(12) Patent Application Publication
(10) Pub. No.: US 2009/0206878 A1
(43) Pub. Date: Aug. 20, 2009

(54) LEVEL SHIFT CIRCUIT FOR A DRIVING CIRCUIT

(75) Inventor: Wen-Teng Fan, Tainan County (TW)

Correspondence Address: J C PATENTS, INC., 4 VENTURE, SUITE 250, IRVINE, CA, 92618, US

(73) Assignee: HIMAX TECHNOLOGIES LIMITED, Tainan County (TW)

(21) Appl. No.: 12/031,162

(22) Filed: Feb. 14, 2008

(51) Int. Cl. H03K 19/0175

(52) U.S. Cl. 326/80; 327/333

(57) ABSTRACT

Provided is a level shift circuit for a driving circuit. The level shift circuit includes: a cross-coupled transistor pair, for receiving a first input signal and a second input signal and for providing a first output signal and a second output signal; a first transistor, coupled to a first power supply and to the cross-coupled transistor pair, further receiving a first control signal; a second transistor, coupled to the cross-coupled transistor pair and for receiving a second control signal; and a third transistor, coupled to the cross-coupled transistor pair and for receiving the second control signal. The first control signal, the second control signal, the first output signal and the second output signal are all referenced to the first power supply, and the first input signal and the second input signal are referenced to a second power supply lower than the first power supply.

### BACKGROUND OF THE INVENTION

1. Field of Invention

The present invention relates to a level shift circuit for a driving circuit.

2. Description of Related Art

Various types of electronic devices have display devices, such as TVs, laptop computers, monitors and mobile communication terminals. The display devices are requested to be thin and/or light in order to save the volume and the cost of the electronic devices. To satisfy these requirements, various Flat Panel Displays (FPDs) have been developed as alternatives to more conventional cathode ray tube displays.

A Liquid Crystal Display (LCD) is one kind of Flat Panel Display. FIG. 1 is a block diagram illustrating functional elements of an LCD device. As illustrated in FIG. 1, an LCD device 2 includes a timing controller 3, a gate driver 4, a LCD panel 5 and a source driving circuit 100.

An image is displayed by applying voltage into the common electrode and the pixel electrode, and then controlling intensity of the electric field to control transmittance of light of the liquid crystal.

The LCD panel 5 includes a plurality of gate lines, data lines which respectively are arranged substantially in perpendicular direction with respect to the gate line, and unit pixels which are formed on the points that each of the gate lines and data lines intersect at right angles. A typical unit pixel may include an LCD capacitor and a switching TFT (Thin Film Transistor).

RGB (Red, Green, Blue) data are into the LCD device 2 from an external host system 1, e.g., a graphic source. The data format of the input RGB data is converted by the timing controller 3 of the LCD device 2, and transmitted to the source driving circuit 100. In addition, the timing controller 3 generates various control signals to apply the various control signals into the source driving circuit 100 and gate driver 4.

The gate driver 4 receives the control signals and digital data from the timing controller 3 and applies gate driving signals into the gate lines, thereby sequentially driving each of the gate lines.

The source driving circuit 100 receives control signals and digital data from the timing controller 3, and transforms the digital data into analog gray scale voltages for driving the LCD panel 5 according to the applied control signals, thereby applying the analog gray scale voltages into the data lines of the LCD panel 5, then to cause the LCD panel 5 display an image.

Generally, the bit number of the RGB input into the timing controller 3 needs to be the same as that of the data signal of the source driving circuit 100. In general, a color depth of 18-bits (i.e. each of the Red, Green, Blue data is 6 bits (n=6)), or 24-bits (i.e. each of the Red, Green, Blue is 8 bits (n=8)) is commonly used in LCDs.

FIG. 2 is a block diagram illustrating the source driving circuit 100 illustrated in FIG. 1.

Referring to FIG. 2, the source driving circuit 100 includes a control circuit 101, a register circuit 102, a level shift circuit 200, a digital to analog converter 103 and an amplifying circuit 104.

The control circuit 101 receives the control signals, such as SSP (Source driving circuit Start Pulse) and data clock, etc., from the timing controller 3 and controls each of the circuits 102, 200, 103 and 104. The control circuit 101 receives digital data, i.e. RGB code, from the timing controller 3 and applies the digital signal into corresponding circuits.

The register circuit 102 stores the digital data applied from the control circuit 101. Because the register circuit 102 and the digital-to-analog converter 103 operate at low voltage and at high voltage respectively, the level shift circuit 200 transforms the voltage level of the outputs of the register circuit 102 so that the digital data provided from the register circuit 102 can be input to the digital-to-analog converter 103.

FIG. 3 shows a circuit diagram of the conventional level shift circuit 200. The level shift circuit 200 comprises a cross-coupled transistor pair, i.e. pull-down transistors 201 and 202, and pull-up transistors 203 and 204. Explanation of the various connections between the transistors 201, 202, 203 and 204 is omitted for brevity as those connections can be easily seen and understood from inspection of FIG. 3. The sources of the pull-down transistors 201 and 202 are connected to a ground terminal 1S GND. The sources of the pull-up transistors 203 and 204 are connected to a power supply VDDA. The gates of the pull-down transistors 201 and 202 are connected to input signals IN and INB individually. The signal INB is substantially an inverted signal of the signal IN, i.e. these two input signals IN and INB are complementary to each other. Besides, the output signals OUT and OUTB of the level shift circuit 200 are substantially inverted to each other, i.e. these two output signals OUTB and OUT are complementary to each other.

FIG. 4 shows waveforms of the input signal IN and the output signal OUT of the level shift circuit 200. As mentioned above, the input signal INB and output signal OUTB are substantially inverted signals to the signals IN and OUT individually. The input signal IN has high voltage level VDDD and low voltage level GND. The output signal OUT has high voltage level VDDA and low voltage level GND. Furthermore, the voltage level VDDA is higher than VDDD. Operation of the level shift circuit 200 is explained with respect to FIG. 4.

When the input signal IN is at the low voltage level GND, the pull-down transistor 201 is turned off, while the pull-down transistor 202 is turned on for pulling the output signal OUT down to GND. The LOW output signal OUT turns on the pull-up transistor 203, pulling the output signal OUTB high to VDDA. Meanwhile, the HIGH output signal OUTB turns off the pull-up transistor 204, insuring that the output signal OUT remains low.

On the other hand, when the input signal IN is at the high voltage level VDDD, the pull-down transistor 201 is turned on for pulling the output signal OUTB down to GND. The LOW output signal OUTB turns on the pull-up transistor 204, pulling the output signal OUT high to VDDA. Meanwhile, the HIGH output signal OUT turns off the pull-up transistor 203, insuring that the output signal OUTB remains low.

However, accompanied with remarkable advances in semiconductor fabrication process for low power consumption application, VDDD is lower and lower year by year. Lower VDDD is crucial to the pull-down transistors 201 and 202. Lower VDDD means lower gate-source voltage difference V_{gs} of the pull-down transistor 201 and 202. As gate-source voltage difference V_{gs} becomes lower and lower, the saturation current through the pull-down transistors also becomes smaller and smaller. So it is difficult to transit both the output signals OUT and OUTB from the high voltage level VDDA into the low voltage level GND, i.e. the “pull low” ability of the pull-down transistors may not enough.

Consequently, it is desirable to provide a level shift circuit which can work well with low voltage level VDDD.

### SUMMARY OF THE INVENTION

The invention provides a level shift circuit. In the level shift circuit, two additional pull-down transistors with high driving force are used for enhancing transition of output signals from H to L while a further transistor is used for preventing power-ground short during transition.

The cross-coupled transistor pair has five nodes. The first one is connected to the first transistor; the second one provides a first output signal; the third one provides a second output signal; the fourth one receives a first input signal; and the fifth one receives a second input signal.

The first output signal is substantially an inverted signal of the second output signal, i.e. these two output signals are complementary to each other. Both the complementary output signals have voltage levels between a first power supply and ground terminal. Similarly, the first input signal is substantially an inverted signal of the second input signal, i.e. these two input signals are complementary to each other. Both the complementary input signals have voltage levels between a second power supply and ground terminal.

The first transistor has a source coupled to the first power supply, a drain connected to the first node of the cross-coupled transistor pair, and a gate for receiving a first control signal.

The second transistor has a source coupled to ground terminal, a drain coupled to the third node of the cross-coupled transistor pair, and a gate for receiving a second control signal.

The third transistor has a source coupled to ground terminal, a drain coupled to the second node of the cross-coupled transistor pair, and a gate for receiving the second control signal.

As mentioned above, the first control signal and the second control signal have voltage levels between the first power supply and ground terminal, i.e. the same as the first output signal and the second output signal, not the first input signal and the second input signal between the second power supply and ground terminal.

Besides, the logic H period of the second control signal is covered by the logic H period of the first control signal. At the logic H period of the first control signal, the first transistor is turned off to prevent short between the first power supply and ground terminal. At the logic H period of the second control signal, at least one of the second and the third transistors is turned on for pulling at least one of the first and the second output signal to logic L. Furthermore, the second and the third transistors have higher pull low ability than corresponding transistors in the cross-coupled transistor pair. Finally, after the first control signal goes logic L, the first and the second output signals are determined by the cross-coupled transistor pair.

From above mentioned, even though the second power supply becomes lower, three additional transistors the first, the second and the third transistor are used to enhance pull low ability for the first and the second output signals.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a block diagram illustrating functional elements of an LCD (Liquid Crystal Display) device.

FIG. 2 shows a block diagram illustrating the source driving circuit 100 illustrated in FIG. 1.

FIG. 3 shows a circuit diagram of the conventional level shift circuit 200 illustrated in FIG. 2.

FIG. 4 shows waveforms of the input signal IN and the output signal OUT of the level shift circuit 200 in FIG. 3.

FIG. 5A shows a circuit diagram of a level shift circuit according to an embodiment of the invention.

FIG. 5B and FIG. 5C show signal waveforms of the level shift circuit 300 in FIG. 5A.

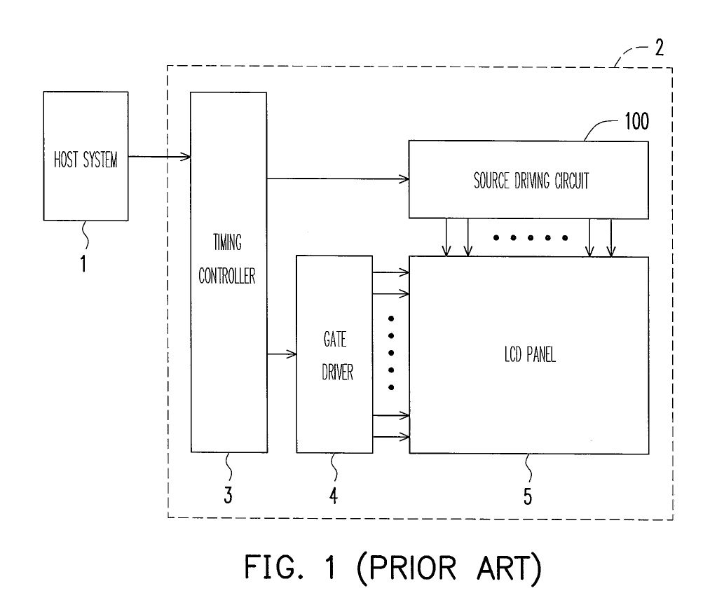

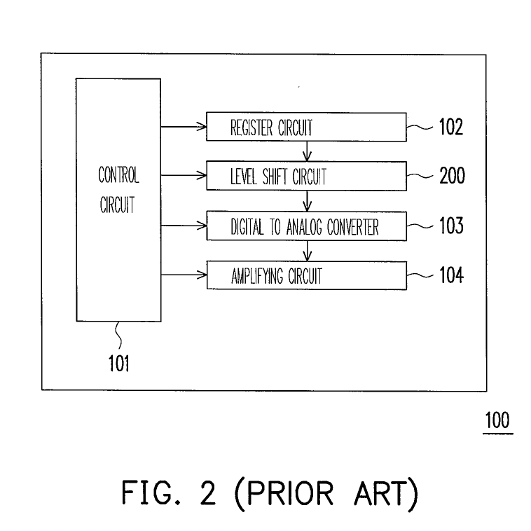

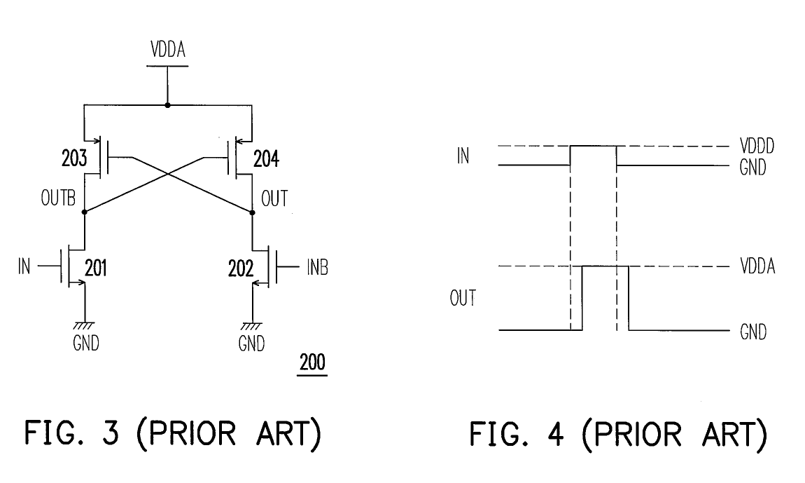

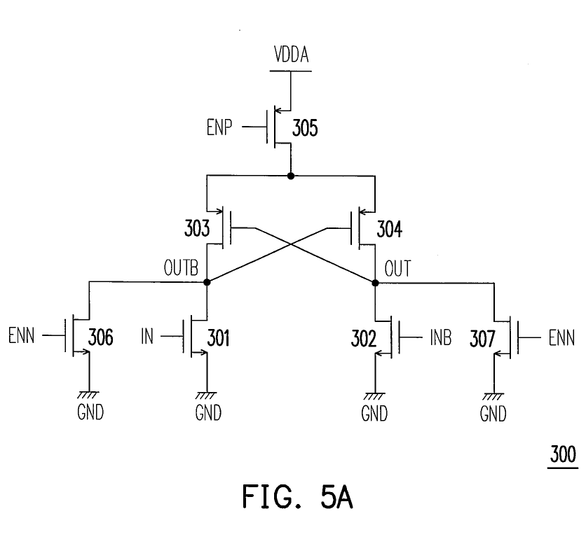

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts. The ground terminal GND is not limited to the ground, it may be another power supply voltage VSSA.

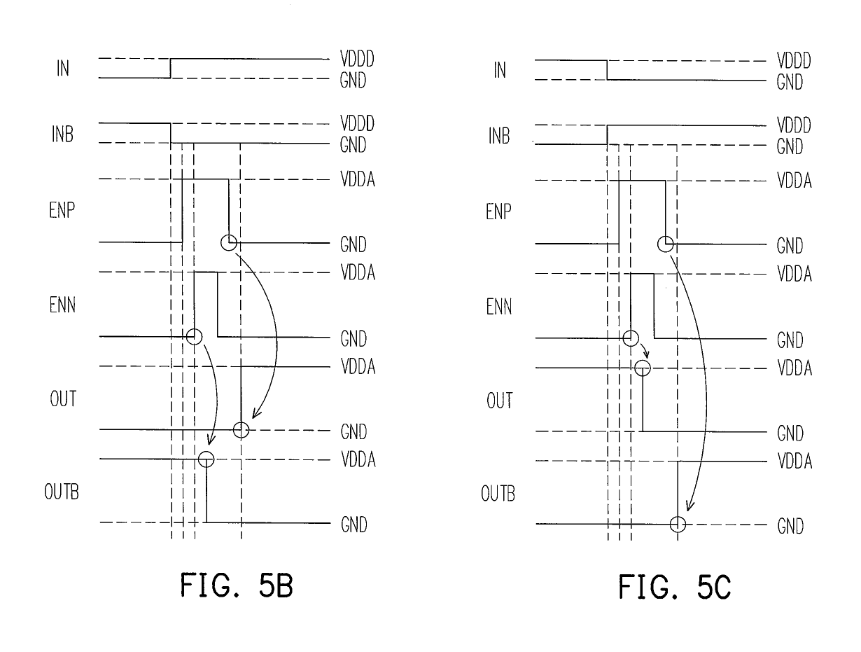

FIG. 5A shows a circuit diagram of a level shift circuit 300 according to an embodiment of the invention. The level shift circuit 300 comprises two pull-down transistors 301 and 302, two pull-up transistors 303 and 304, and three additional transistors 305, 306 and 307.

The transistor 301 has a source coupled to ground terminal GND, a drain for providing an output signal OUBT, and a gate for receiving an input signal IN.

The transistor 302 has a source coupled to ground terminal GND, a drain for providing an output signal OUT, and a gate for receiving an input signal INB.

The transistor 303 has a source coupled to the transistor 305, a drain for providing the output signal OUTB, and a gate coupled to the output signal OUT.

The transistor 304 has a source coupled to the transistor 305, a drain for providing the output signal OUT, and a gate coupled to the output signal OUTB.

The transistor 305 has a source coupled to a power supply VDDA, a drain coupled to both the source of the transistors 303 and 304, and a gate for receiving a control signal ENP.

The transistor 306 has a source coupled to ground terminal GND, a drain coupled to the output signal OUTB, and a gate for receiving a control signal ENN.

The transistor 307 has a source coupled to ground terminal GND, a drain coupled to the output signal OUT, and a gate for receiving the control signal ENN.

The control signal ENP, the control signal ENN, the output signals OUTB and OUT have voltage levels between the power supply VDDA and ground terminal GND. The input signals IN and INB have voltage levels between a power supply VDDD and ground terminal GND, and VDDD<VDDA.

Furthermore, the output signal OUTB is substantially an inverted signal of the output signal OUT, i.e. these two output signals are complementary to each other. The signal IN is substantially an inverted signal of the input signal INB, i.e. these two input signals are complementary to each other.

FIG. 5B and FIG. 5C show waveforms of the input signal IN, the input signal INB, the control signal ENP, the control signal ENN, the output signal OUTB and the output signal OUT of FIG. 5A. Operation of the level shift circuit 300 is explained with respect to FIG. 5B and FIG. 5C.

After the input signal IN is changed from logic L to logic H (the high voltage level VDDD), the control signal ENP is changed to the high voltage level VDDA, and then the control signal ENN goes to the high voltage level VDDA for turning on the transistor 306 and pulling the output signal OUTB low to GND. After the output signal OUTB is already LOW, the control signal ENN goes to the low voltage level GND, and then the control signal ENP goes to the low voltage level GND for turning on the transistor 304 and pulling the output signal OUT high to VDDA. Meanwhile, because the output signal OUT goes high, the transistor 303 is turned off for insuring that the output signal OUTB remains low.

On the other hand, when the input signal IN is changed from logic H to logic L at the low voltage level GND, i.e. the input signal INB is changed form logic L to logic H, the control signal ENP is changed to the high voltage level VDDA, and then the control signal ENN goes to the high voltage level VDDA for turning on the transistor 307 and pulling the output signal OUT low to GND. After the output signal OUT is already LOW, the control signal ENN goes to the low voltage level GND, and then the control signal ENP goes to the low voltage level GND for turning on the transistor 303 pulling the output signal OUTB high to VDDA. Meanwhile, because the output signal OUTB goes high, the transistor 304 is turned off for insuring that the output signal OUT remains low.

Besides, the logic H period of the control signal ENN is covered by the logic H period of the control signal ENP. At the logic H period of the control signal ENP, the transistor 305 is turned off to prevent current leakage. At the logic H period of the control signal ENN, at least one of the transistors 306 and 307 is turned on for pulling at least one of the output signal OUTB and OUT to logic L. Furthermore, the transistors 306 and 307 have higher pull low ability than the two pull-down transistors 301 and 302. Finally, after the control signal ENP goes logic L, the output signals OUTB and OUT are determined by the transistors 301, 302, 303 and 304.

From above mentioned, even though the power supply VDDD becomes lower, the transistors 305, 306 and 307 are used to enhance pull low ability for the output signals OUTB and OUT.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

1. A level shift circuit for a driving circuit, comprising:
a cross-coupled transistor pair, having a first node, a second node for providing a first output signal, a third node for providing a second output signal, a fourth node for receiving a first input signal and a fifth node for receiving a second input signal;
a first transistor, having a first terminal coupled to a first power supply, a second terminal coupled to the first node of the cross-coupled transistor pair and a control terminal for receiving a first control signal;
a second transistor, having a first terminal coupled to a predetermined voltage, a second terminal coupled to the third node of the cross-coupled transistor pair and a control terminal for receiving a second control signal; and
a third transistor, having a first terminal coupled to the predetermined voltage a second terminal coupled to the second node of the cross-coupled transistor pair and a control terminal for receiving the second control signal,
wherein the first control signal, the second control signal, the first output signal and the second output signal are all referenced to the first power supply, and the first input signal and the second input signal are referenced to a second power supply lower than the first power supply,
wherein during a transition, the first transistor is turned off, and the second transistor and the third transistor are turned on so as to set the second node and the third node to the predetermined voltage.
wherein after the transition, the first transistor is turned on, and the second transistor and the third transistor are turned off so as to output the first output signal and the second output signal according to the first input signal and the second input signal.

2. The level shift circuit of claim 1, wherein the predetermined voltage is GND.

3. (canceled)

4. The level shift circuit of claim 1, wherein the first output signal is substantially an inverted signal of the second output signal after the transition.

5. The level shift circuit of claim 1, wherein the first input signal is substantially an inverted signal of the second input signal.

6. The level shift circuit of claim 1, wherein the first control signal is corresponding to preventing short between the first power supply and the predetermined voltage.

7. The level shift circuit of claim 1, wherein during the transition, the first control signal turns off the first transistor for a first period, the second control signal turns on the second transistor and the third transistor for a second period, and the second period in smaller than the first period.

8. The level shift circuit of claim 1, wherein the second transistor and the third transistor have higher pull low ability than corresponding transistors in the cross-coupled transistor pair.

9. (canceled)

10. A level shift circuit for a driving circuit, comprising:
a first transistor, having a first terminal coupled to a predetermined voltage, a second terminal for providing a first output signal and a control terminal for receiving a first input signal;
a second transistor, having a first terminal coupled to the predetermined voltage, a second terminal for providing a second output signal and a control terminal for receiving a second input signal;
a third transistor, having a first terminal, a second terminal for providing the first output signal and a control terminal coupled to the second output signal;
a fourth transistor, having a first terminal, a second terminal for providing the second output signal and a control terminal coupled to the first output signal;
a fifth transistor, having a first terminal coupled to a first power supply, a second terminal coupled to both the first terminals of the third and the fourth transistors and a control terminal for receiving a first control signal;
a sixth transistor, having a first terminal coupled to the predetermined voltage, a second terminal coupled to the first output signal and a control terminal for receiving a second control signal; and
a seventh transistor, having a first terminal coupled to the predetermined voltage, a second terminal coupled to the second output signal and a control terminal for receiving the second control signal,
wherein the first control signal, the second control signal, the first output signal and the second output signal are all referenced to the first power supply, and the first input signal and the second input signal are referenced to a second power supply lower than the first power supply,
wherein during a transition, the fifth transistor is turned off, and the sixth transistor and the seventh transistor are turned on so as to set the second node and the third node to the predetermined voltage.
wherein after the transition, the fifth transistor is turned on, and the sixth transistor and the seventh transistor are turned off so as to output the first output signal and the second output signal according to the first input signal and the second input signal.

11. The level shift circuit of claim 10, wherein the first output signal is substantially an inverted signal of the second output signal after the transition.

12. The level shift circuit of claim 10, wherein the first input signal is substantially an inverted signal of the second input signal.

13. The level shift circuit of claim 10, wherein the first control signal turns off the fifth transistor for preventing short between the first power supply and the predetermined voltage.

14. The level shift circuit of claim 10, wherein during the transition, the first control signal turns off the fifth transistor for a first period, the second control signal turns on the sixth transistor and the seven transistor for a second period, and the second period in smaller than the first period.

15. The level shift circuit of claim 10, wherein the sixth transistor and the seventh transistor have higher pull low ability than the first transistor and the second transistor.

16. (canceled)

17. The level shift circuit of claim 10, wherein the predetermined voltage is GND.
